(19) United States
(12) Patent Application Publication
(10) Pub. No.: US 2026/0030423 A1
(43) Pub. Date: Jan. 29, 2026

(54) QUANTUM TECHNOLOGY COMPUTER-AIDED DESIGN SYSTEM

(71) Applicant: Quantum Elements Inc., Palo Alto, CA (US)

(72) Inventors: Dor Gabay, Jacksonville, FL (US); Amir Yacoby, Newton, MA (US); Daniel Lidar, La Canada, CA (US); Izhar Medalsy, Thousand Oaks, CA (US)

(21) Appl. No.: 18/652,557

(22) Filed: May 1, 2024

Related U.S. Application Data
(60) Provisional application No. 63/499,877, filed on May 3, 2023.
(60) Provisional application No. 63/515,456, filed on Jul. 25, 2023.

(51) Int. Cl. G06F 30/3308

(52) U.S. Cl. CPC G06F 30/3308

(57) ABSTRACT

A quantum technology computer aided design system characterizes and optimizes semiconductor-based qubit systems based on user-provided information through physical and dynamic simulations of the system using sets of solvers. The physical simulations employ a self-consistent Poisson-Schrodinger process that includes both Fock and Configuration Interaction calculations for generating the set of lowest-energy eigenenergies and eigenfunctions representing the user-specified qubit(s) in the presence of some DC gate voltages. The eigenenergies and eigenfunctions are used to evaluate quality control metrics of the semiconductor-based qubit system for a range of gate voltages. The dynamic simulations are facilitated through extraction of physical parameters of the semiconductor-based qubit system from the physical simulations to a first-quantized effective Hamiltonian, followed by the mapping of the first-quantized effective Hamiltonian to a second-quantized effective Hamiltonian used to dynamically model qubit operations within an open quantum system framework and extract their performance metrics in the presence of relevant noise sources.

### RELATED APPLICATIONS

This is a NONPROVISIONAL and claims the priority benefit of U.S. Provisional Application No. 63/499,877, filed May 3, 2023, and U.S. Provisional Application No. 63/515,456, filed Jul. 25, 2023, each of which is incorporated herein by reference in its entirety.

### FIELD OF THE INVENTION

The present invention relates to a computer-aided design system for quantum technology, and more specifically to such a system for use in connection with the design, fabrication, and control of semiconducting quantum devices.

### BACKGROUND

A quantum computer is a computing device that exploits quantum mechanical phenomena in its operation. It is generally believed that quantum computers are better suited to some computational tasks than conventional computers that do not exploit these phenomena. One hallmark of quantum computers is that their basic unit of information is the qubit, which, unlike conventional bits familiar to users of conventional computers, can exist in a superposition of states. By exploiting this and other properties of qubits, quantum computers are able to perform certain calculations that cannot feasibly be performed by conventional computers in an efficient manner.

To date, experimentalists have explored a variety of different qubit implementations. Qubits that are based on the spin states of trapped electrons (“spin qubits”), which form the information elements of Loss-DiVincenzo quantum computers, are of particular interest, in part because of the existing industry in the field of semiconductor design and fabrication. Notwithstanding this expertise, however, designing and implementing qubits remains a challenging problem.

### SUMMARY OF THE INVENTION

In one embodiment, a quantum technology computer-aided design (Q-TCAD) system includes a user interface (UI) configured to allow a user to characterize a semiconductor-based qubit system by defining a physical architecture, prescribing materials, optimizing system properties, choosing quality control and performance metrics, specifying simulation preferences, and defining input signals for said semiconductor-based qubit system; and a qubit modeling stage that is configured to receive user inputs through the UI and to run both physical and dynamic simulations of the semiconductor-based qubit system as specified through the UI, said simulations run using a set of solvers, wherein the physical simulations: employ a self-consistent Poisson-Schrodinger process that includes both Fock and Configuration Interaction calculations for generating a set of lowest-energy eigenenergies and eigenfunctions representing the semiconductor-based qubit system in the presence of DC gate voltages, and evaluate quality control metrics of the semiconductor-based qubit system for a range of said gate voltages, and wherein the dynamic simulations are facilitated through extraction of physical parameters of the semiconductor-based qubit system from the physical simulations to a first-quantized effective Hamiltonian, followed by a mapping of the first-quantized effective Hamiltonian to a second-quantized effective Hamiltonian used to dynamically model qubit operations within an open quantum system framework, the dynamic simulations entailing simulation of applications of sequences of RF pulses applied to gates of the semiconductor-based qubit system and evaluation of performance metrics for each such operation in the presence of dynamic noise sources.

The qubit modeling stage of the Q-TCAD system may be configured to (a) permit manual user definition of the semiconductor-based qubit system, and/or (b) permit definition of the semiconductor-based qubit system through receipt and automated analysis of one or more images (e.g., scanning electron micrographs (SEMs)) of one or more elements (e.g., a physical gate structure for semiconductor qubits) of the semiconductor-based qubit system.

Additionally, the qubit modeling stage may be configured to permit qubit type characterization by one or more of physical makeup, atomic configuration, charge configuration, loading, readout, initialization, one-qubit operation, and two-qubit operation. Also, the qubit modeling stage may be configured to permit user definition of one or more of material and physical design defects, including some or all of charge impurities, atomic steps, and dangling bonds, within a semiconducting heterostructure of the semiconductor-based qubit system. Such material and physical design defects may be incorporated into the physical and dynamic simulations to account for fabrication yields during manufacture of the semiconducting heterostructure and fabrication of the semiconductor-based qubit system. In some embodiments, the qubit modeling stage of the Q-TCAD system may be configured to run the physical and dynamic simulations recursively according to a specified optimization protocol, whether for qubit characterization or a quantum control protocol.

In various embodiments, the solvers of the Q-TCAD system separate a semiconducting heterostructure of the semiconductor-based qubit system characterized through the UI into classical and quantum regimes, the classical regime being defined by a nonlinear Poisson equation with boundary conditions (BCs) applied to an exterior of the semiconducting heterostructure and a corresponding metal-semiconductor interface, and the quantum regime being characterized by either a multi-band k.p method, an effective mass theory (EMT), a nonperturbative multi-valley effective mass theory (MV-EMT), or a tight-binding (TB) scheme. The solvers may include a micromagnetic solver to characterize external magnetic field distribution from micromagnetic islands. Additionally, the solvers may be configured to provide electrostatic or electromagnetic fields of collective DC and RF gates by evaluating a Poisson integral or evaluating a 4-vector (scalar-vector) potential in its integral (differential) form, respectively.

In some embodiments, the semiconductor-based qubit system characterized through the UI may be a model of a system that includes a plurality of semiconductor qubits, each of which is a collection of electrons trapped within a quantum dot (QD)-like structure, where the QDs are defined by adjusting voltages applied to physical gates above a semiconducting heterostructure. Alternatively, the semiconductor-based qubit system characterized through the UI may be a model of a system that includes a plurality of semiconductor qubits, where the semiconductor qubits are: charge qubits, donor qubits, color centers, or other qubits operated within semiconducting materials.

In some embodiments of the present Q-TCAD system, the dynamic noise sources are one or more of 1/f charge noise, spin dephasing due to hyperfine interactions, and phonon-mediated relaxation. And, as part of the physical simulations, atomistic calculations may be used to extract material parameters for a prescribed Schrodinger equation. Such atomistic calculations may be tight binding calculations. The material parameters extracted for a prescribed Schrodinger equation may include one or more of an effective mass within a nonperturbative multi-valley effective mass, a conduction band offset, spin-orbit band shifts, valance band strain, conduction band strain, and Luttinger-Kohn parameters.

A further embodiment of the present invention provides a Q-TCAD system that includes a UI configured to allow a user to characterize a semiconductor-based qubit system by defining a physical architecture, prescribing materials, optimizing system properties, choosing quality control and performance metrics, specifying simulation preferences, and defining input signals for said semiconductor-based qubit system; and a qubit modeling stage that is configured to receive user inputs through the UI and to run both physical and dynamic simulations of the semiconductor-based qubit system, wherein the physical simulations produce quality control metrics for the semiconductor-based qubit system and the dynamic simulations produce performance metrics of qubit operations. In some embodiments of such a Q-TCAD system, the physical parameters of the semiconductor-based qubit system extracted from physical simulations may be placed within a first-quantized effective Hamiltonian which is mapped to a second-quantized effective Hamiltonian used to dynamically model the qubit operations. For example, the first-quantized effective Hamiltonian may be mapped to a second-quantized effective Hamiltonian by a Schrieffer-Wolf transformation.

These and further embodiments of the present invention are described in greater detail below.

### BRIEF DESCRIPTION OF THE DRAWINGS

The present invention is illustrated by way of example, and not limitation, in the figures of the accompanying drawings, in which:

FIG. 1 illustrates an example of a functional representation of a system for semiconductor qubit characterization using physical models and for studying performance metrics of the operation of semiconductor qubits within an effective model, in accordance with an embodiment of the present invention.

FIG. 2 illustrates an example of a physical design layout of a qubit system for characterization by a system for semiconductor qubit characterization such as that illustrated in FIG. 1.

FIG. 3 illustrates a cross-section of a quantum dot spin qubit taken along line FIG. 3-FIG. 3 in FIG. 2.

FIG. 4 illustrates an example of a physical simulation module for semiconductor qubit characterization such as that illustrated in FIG. 1.

### DETAILED DESCRIPTION

The present inventors have devised a quantum technology computer-aided design (Q-TCAD) system to address challenges with respect to the design, fabrication, and control of semiconducting quantum devices. In one embodiment, the Q-TCAD system provides for both quantum computer aided design (QAD) and quantum design automation (QDA). The former allows a user to define the physical layout of individual qubit components, characterize them, optimize them, control them, and test their fabrication yield. The latter allows the user to design and simulate quantum chips on the component level and study their functionality, fault tolerance, and manufacturability.

As will be explained in greater detail below, the QAD features of the present system allow quantum system developers to reliably fabricate high-fidelity, high-yield qubit components through physical and dynamic simulations. To accomplish this, the Q-TCAD system automatically characterizes semiconductor qubits using physical models and produces performance metrics of their operations within an effective model.

Quantum chip design automation entails designing a reliable chip architecture for the purpose of quantum information processing using well established quantum components. Quantum chip modeling is divided into five categories: design, simulation, analysis and verification, manufacturing preparation, and functional safety. In the design category, users of the Q-TCAD system can build higher-level components (e.g., logical gates, logical qubits, quantum bus architectures, quantum registers, etc.) out of a collection of physical qubits without defining any particular physical layout. The higher-level components undergo logic synthesis to simplify the circuit design for users by emulating their higher-level specifications to a layout of physical qubits. The placement, routing, and compression design of the physical qubits are defined by a standard protocol that is later improved by simulations. These simulations improve the efficiency and production yield of the physical circuit design using Open Quantum System (OQS) and electromagnetic simulations by accounting for (1) the proper placement and routing of physical qubits to mitigate unwanted crosstalk; (2) environmental affects resulting from spurious material defects such as atomic steps or charge impurities; and (3) dynamic noise such as the nuclear spin bath or charge noise. In OQS simulations, each physical qubit is defined by its logical qubit states, a simplified model of the physical qubit articulated via first principles in the QAD stage. Various metrics of the circuit design are defined. For example, a fidelity map of qubit operations within the physical circuit is generated by running OQS simulations on subsets of physical qubits.

The analysis and verification portion of the Q-TCAD system is composed of functional verification, timing analysis, and physical verification. Functional verification ensures that the logical design conforms to specification (i.e., does what it is intended to do). Timing analysis simulates certain elements of the physical circuit to determine timing and delays associated to its logic. Physical verification checks whether the design is physically manufacturable and allows the user to ensure that the resulting chip is not prone to function-preventing physical defects (e.g., electrostatic discharge).

The manufacturing preparation portion of the Q-TCAD system provides mask data preparation in which lithography photomasks are designed to physically manufacture the chip. The functional safety portion of the Q-TCAD system includes an analysis, synthesis, and verification stage. The analysis stage simulates the failure-in-time (FIT) rates of the circuit design. The synthesis stage adds reliability components to the circuit to improve fault detection. The verification stage runs a “fault campaign” by inserting faults into the circuit design to verify the reliability of the circuit functionality.

In one embodiment the Q-TCAD system includes a user interface (UI) and a qubit modeling stage. The qubit model may represent a semiconductor-based qubit system that includes a plurality of semiconductor qubits, each of which is a collection of electrons trapped within quantum dot (QD)-like structures, where the QDs are defined by adjusting voltages applied to physical gates above a semiconducting heterostructure. In other instances, the qubit model may represent other types of semiconductor qubits. These may include donor spin qubits, charge qubits, and color centers, among other semiconductor qubits.

The UI is configured to allow a user to characterize a semiconductor-based qubit system by specifying a semiconductor qubit type, choosing desired procedures for each qubit operation, prescribing quantum sensors, specifying preferred system and performance metrics, setting physical gate voltages, and defining a physical design. In various embodiments, some or all of these factors may be selected using provided default options or through prescribed user inputs. Also, specification or selection of some inputs may result in the automated selection or specification of other input parameters. Throughout the physical design process, the user can choose a substrate, define thickness and doping concentrations of each layer, prescribe materials, create a gate layout, define doping regions, and design ferromagnetic islands, if any.

The qubit modeling stage is configured to receive user inputs through the UI and to run both physical and dynamic simulations of the semiconductor-based qubit system as specified through the UI, with both simulations run using a set of solvers. The physical simulations embody self-consistent Poisson-Schrodinger-CI process, accompanied by Fock and Configuration Interaction calculations for determining exchange and correlation effects, respectively. These solvers are used to accurately determine a set of eigenenergies and eigenfunctions for different configurations of gate voltages and magnetic field distributions. A set of quality control metrics defined by physical observables of the semiconductor qubit architecture are evaluated using the set of eigenenergies and eigenfunctions. The qubit is then characterized by treating the quality control metrics as cost functions within the allotted optimization schemes. Qubit characterization amounts to determining the gate voltage range with which the qubit exists and the subset of gate voltage ranges that enable each of its qubit operations.

The dynamic simulations are facilitated by first mapping the physical Hamiltonian to an effective one. The effective Hamiltonian is composed of a set of (time-dependent) coefficients defined by the eigenenergies and eigenfunctions generated by physical simulations. The dynamic simulator is used to simulate qubit operations using the effective Hamiltonian within an OQS framework, where dynamic noise can be incorporated and plays a prior role in determining qubit performance. For each qubit operation, RF pulses are applied to the physical gates above the semiconducting heterostructure and modified, if necessary, using quantum control protocols to maximize qubit performance metrics. In some cases, an alternative mapping procedure, such as a Schrieffer-Wolf transformation, may be used for effective modeling.

In some embodiments, the qubit modeling stage may be configured to permit manual user definition of the semiconductor-based qubit system. Alternatively, or in addition, the system modeling stage may be configured to permit definition of the semiconductor-based qubit system through receipt and automated analysis of one or more images of one or more elements of the semiconductor-based qubit system. Such images may be, for example, scanning electron micrographs (SEMs) of a physical gate structure for the semiconductor qubits of the semiconductor-based qubit system.

In some embodiments, the qubit modeling stage may be configured to permit the characterization of a qubit type using its charge configuration and associated qubit states, along with one or more if its loading, readout, initialization, one-qubit operation, and two-qubit operation methodologies. In addition, the qubit modeling stage may be configured to permit user definition of one or more material defects, including but not limited to charge impurities, atomic steps, and dangling bonds within the semiconducting heterostructure. Such material defects may be incorporated into the physical and dynamic simulations to account for fabrication yields during manufacture of a semiconducting heterostructure of the semiconductor-based qubit system. The qubit modeling stage may also be configured to run the physical and dynamic simulations recursively according to one or more specified optimization protocols.

In various embodiments, the solvers of the Q-TCAD system separate the semiconducting heterostructure of the semiconductor-based qubit system characterized through the UI into classical and quantum regimes, the classical regime being defined by a nonlinear Poisson equation with boundary conditions (BCs) applied to an exterior of the semiconducting heterostructure and a corresponding metal-semiconductor interface, and the quantum regime being characterized by either a multi-band k.p method, an effective mass theory (EMT), a nonperturbative multi-valley effective mass theory (MV-EMT), or a tight-binding (TB) scheme. The quantum solvers may include Fock and configuration interaction (CI) calculations to accurately account for exchange and correlation effects (e.g., for proper characterization of interdot tunneling effects). The Thomas-Fermi approximation is used to determine the quasi-Fermi energy and occupation density of each energy-level. All physical simulations are run self-consistently. The classical solvers may include a micromagnetic simulator to characterize the external magnetic field distribution from micromagnetic islands. The classical solvers may further be configured to provide simulations of electrostatic and electromagnetic fields resulting from collective DC and RF gate voltages, respectively, to model spatially varying external electrostatic and vector potentials of the system.

Before describing the present system in detail, some background is useful. Throughout this description, we will use the example of semiconductor spin qubits that make use of quantum dot-like structures for confinement of charge (electrons or holes) through electrostatic gating. In the presence of a magnetic field, the spin state of an electron (or hole) confined in a quantum dot may be used as an encoding, much like an electrical charge on a capacitor may be used as a representation of a logical “1” or “0” in a conventional computer memory. The quantum dots for a qubit system may be defined by adjusting voltages applied to barrier and plunger gates (collectively, the DC gates) disposed above a semiconductor heterostructure. Such semiconductor-based qubits offer certain advantages over other forms of qubit technologies because of their relative long coherence times and the fact that developers can leverage decades of knowhow in conventional semiconductor processing techniques to aid in their fabrication. It should be recognized, however, that the Q-TCAD system described herein is not limited to use in connection with such semiconductor spin qubits and, instead, is applicable to and may be used in connection with other forms of semiconductor-based qubits. References to semiconductor spin qubits is merely for convenience and to assist the reader in understanding the nature and function of the present system.

The present Q-TCAD system provides for quantum technology computer aided design (CAD). It allows a user to define qubit structures, optimize them, control them, and test their fabrication yield, and is tailored to provide quantum hardware engineers tools for reliably fabricating high-fidelity, high-yield qubit architectures through physical and dynamic simulations. This capability may then be extended to more complex architectures through a quantum chip modeling toolset that allows the user to design and simulate quantum chips on the component level and study their functionality, fault tolerance, and manufacturability.

As will become apparent from the discussion provided below, the Q-TCAD system includes a user interface (UI) that allows the user to model the semiconducting system, optimize system properties, choose quality control and performance metrics, specify simulation preferences, and define input signals. In a modeling stage, the user can either manually define the qubit system or provide images, such as scanning electron micrographs (SEMs) showing the physical gate structure for semiconductor qubits, that characterize a particular element of the system. The qubit can be characterized by its physical makeup (e.g., charge, spin, donor, etc.), qubit type, and its user-specified loading, readout, initialization, one-qubit operation, and two-qubit operation methodologies. If the user desires, manually defined material defects such as atomic steps, charge impurities, and dangling bonds can be integrated into the physical model.

More particularly, for the physical simulations used to characterize the semiconductor qubits, electrostatic calculations are used to define an external scalar potential applied to the system in the presence of DC gates. Thereafter, the nonlinear Poisson equation is used to map the semiconductor's electron, hole, ionized donor, and ionized acceptor concentrations to the induced electrostatic potential within the bulk semiconducting heterostructure. A self-consistent Poisson-Schrodinger-CI scheme is then used to minimize the ground-state energies of the system. The Thomas-Fermi approximation is used to determine the quasi-Fermi energy and occupation density of each energy-level. The DC gate voltages, along with the quasi-Fermi energy and other material properties, are used to determine the charge accumulation at the two-dimensional electron (hole) gas (2DEG or 2DHG). The DC gate voltages can either be defined manually (through the UI) or by using an automated tuning procedure. In the latter, the tuning is achieved by applying a bootstrapping, coarse tuning, controllability, and charge state tuning procedure. Bootstrapping entails making the local sensing system (if any) operational and determining the voltage range of the physical gates within the device. Coarse tuning determines the range of gate voltages for which the semiconductor qubit is within a global configuration of charge states. Controllability entails establishing virtual gates out of the physical gates to account for capacitive crosstalk. Charge state tuning ensures that the semiconductor qubit is within the charge configuration of interest. Once these calculations are complete, quality control metrics can be evaluated for the determined gate voltages regimes (e.g., charging energy, interdot tunnel coupling, etc.).

With the quality control metrics available, the semiconductor qubits can be dynamically modeled to define qubit operations. Relevant quality control metrics (e.g., g-tensor, tunnel coupling, etc.) extracted from physical simulations are used to define a first-quantized effective Hamiltonian. The coefficients of a second-quantized effective Hamiltonian, defined by an operator basis expansion such as the Pauli group, are then defined by the first-quantized effective Hamiltonian and the eigenenergies and eigenfunctions generated by physical simulations. The resulting second-quantized effective Hamiltonian is used to dynamically model qubit operations within an OQS framework. An OQS is an extension of a closed quantum system incorporating a non-unitary component that contributes to qubit dephasing. This results in a quantum master equation. The quantum master equation can be used to determine the qubit operation's performance metrics in the presence of relevant noise sources (e.g., relaxation time T₁, decoherence time T₂, fidelity). Qubit operations include loading, initialization, readout, one-qubit operations, and two-qubit operations. For each of these operations, a sequence of RF pulses is applied to physical gates above the semiconducting heterostructure. These RF pulses can be defined (refined) using quantum control protocols. In some cases, an alternative mapping procedure, such as a Schrieffer-Wolf transformation, may be used for effective modeling.

To assess fabrication yield, users can further apply statistical modeling to their qubit design. The system's fabrication yield is dictated by material defects within the semiconducting heterostructure. These material defects are statistically incorporated into physical and dynamic simulations to determine the system's performance metrics. For some set of defect concentrations, the resulting performance metrics can be used to determine the fabrication yield of the system. The resulting fabrication yield can give chip designers a good indication of how to maximize their design's performance metrics in the presence of unavoidable defects.

Users can further optimize the signal input, geometry design, and material properties of their qubit architecture automatically through various quantum control protocols or procedures. In such quantum control procedures (e.g., Chopped Random Basis (CRAB) method, Gradient Ascent Pulse Engineering (GRAPE)), ground state and dynamic modeling calculations can be recursively simulated to optimize a user-defined cost function, such as the fidelity of a given operation. In addition to geometry and material properties, such optimization procedures can drastically eliminate the design overhead associated to system tunability. By automating the tuning procedure, the user can attain a powerful formula of the collection of signals required for high-fidelity qubit operations, eliminating the time and uncertainty of manual efforts at the measurement stage. Once the semiconducting chip is fabricated, a separate quantum control toolkit interfacing with the chip is provided to fine tune DC and RF signals applied to the device.

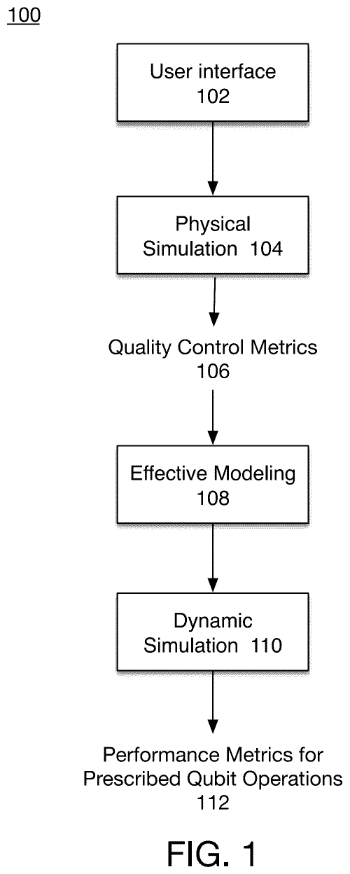

Turning now to FIG. 1, as noted above the present Q-TCAD system 100 provides for semiconductor qubit characterization using physical models and for studying performance metrics of the operation of semiconductor qubits within an effective model. A user interface 102 provides a facility for a user to specify parameters that characterize a semiconductor-based qubit system. These parameters may include qubit type, qubit operation procedures, gate layout, layer thicknesses, material prescription, and other elements of the qubit system physical design. In addition, user interface 102 allows the user to choose quality control metrics, specify simulation preferences, and define input signals for the qubit system.

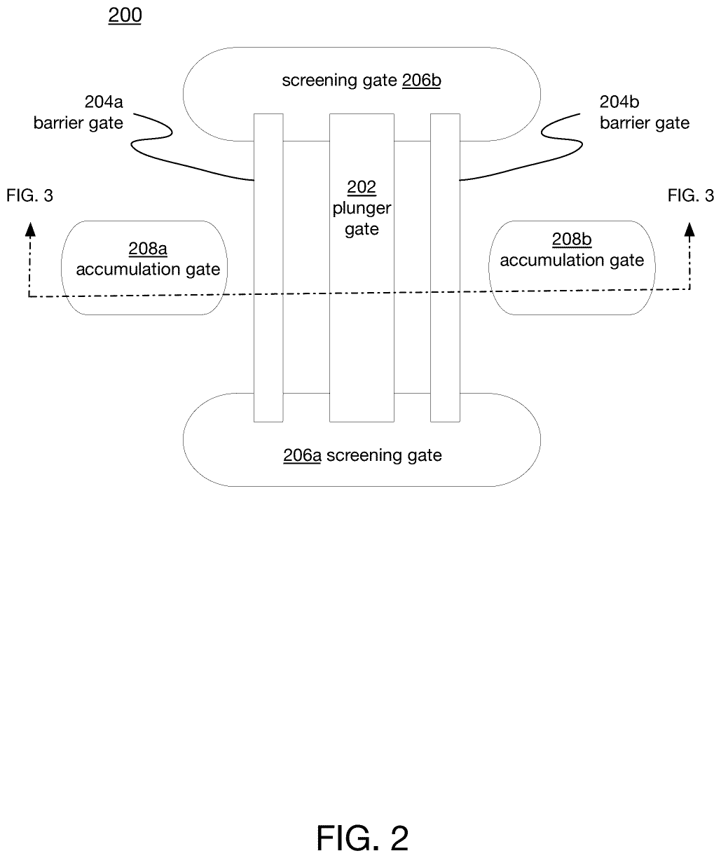

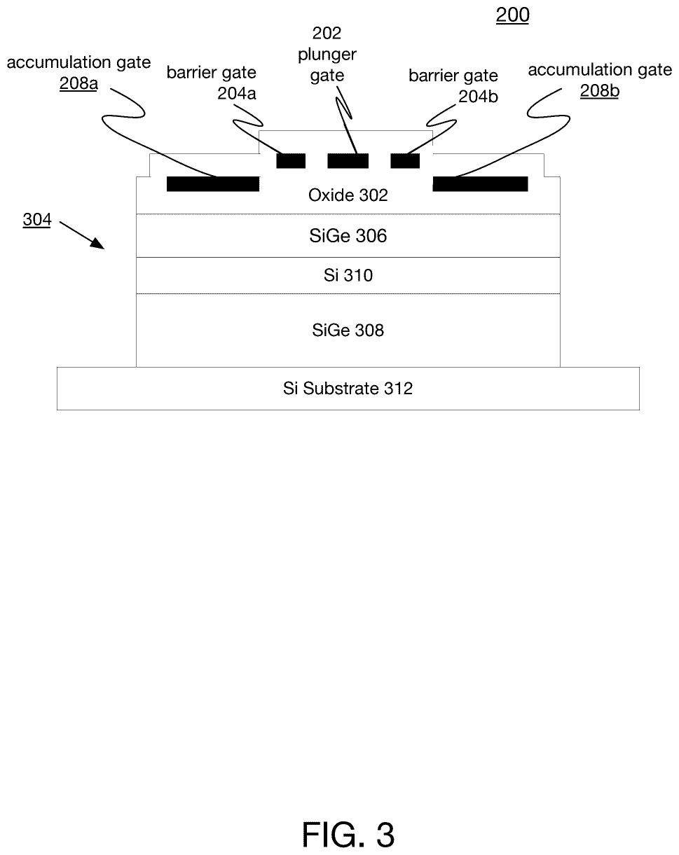

By way of example, and referring to FIG. 2, the user may specify the physical design of a qubit system by defining, in a top-down fashion, an assortment of physical gates within a two-dimensional layout. In FIG. 2, the gate layout of a Si/SiGe quantum dot spin qubit 200 is depicted. Of course, the present system is not limited to modeling Si/SiGe heterostructures and, instead, may be used to model any semiconducting heterostructure material(s). The two-dimensional gate layout is then translated to a set of possible three-dimensional layered gate structures as shown in FIG. 3, which illustrates a cross-section of the quantum dot spin qubit 200 taken along line FIG. 3-Fig. 3 in FIG. 2.

Through the facilities of user interface 102, the user may specify the layout of plunger gate 202, barrier gates 204a, 204b, screening gates 206a, 206b, and accumulation gates 208a, 208b. The gate layout is used to confine a finite number of electrons within dot-like structures at the 2DEG. These gates are padded by a thin oxide layer 302 to isolate them from one another and the semiconducting heterostructure 304, which in this example consists of SiGe layers 306 and 306 with an intervening layer of Si 310, all disposed on a Si substrate 312. Doping regions (not shown) can be defined far away from the dots to carry electrons or holes along the path of the physical gates towards an accumulation region. Ohmic contacts can be inserted to enforce currents along certain regions of the 2DEG. Depending on the foundry and fabrication methodology, the gate layout and the prescribed materials for the physical gates may differ. Furthermore, ferromagnetic islands can be defined above the physical gates to enforce gradient magnetic fields at desired locations of the system. In addition to the gate layout, the user may specify (through user interface 102) the substrate material as well as the desired materials, thicknesses, and doping concentrations of each prescribed layer forming the semiconducting heterostructure 304.

As an alternative to this manual user definition of the semiconductor-based qubit system, user interface 102 may be configured to allow a user to define the semiconductor-based qubit system by providing one or more images of one or more elements of the system. For example, the user may upload one or more SEMs of a physical gate structure for the semiconductor qubits of the semiconductor-based qubit system via user interface 102, and the Q-TCAD system 100 may automatically analyze the SEMs to determine the nature of the gate arrangement. Through iterative interaction with the Q-TCAD system 100 via user interface 102, the user may then edit and refine the gate layout and material structure developed through this automated analysis.

User interface 102 also allows the user to specify DC and RF voltages to be applied at each of the physical gates for a given qubit system. Alternatively, the user may elect to use an automated qubit characterization (tuning) procedure. As part of the automated process, the Q-TCAD system 100 will determine the range of applied gate voltages for which the qubit is well-defined and subsets of the applied gate voltages for which each of the qubit operations occur.

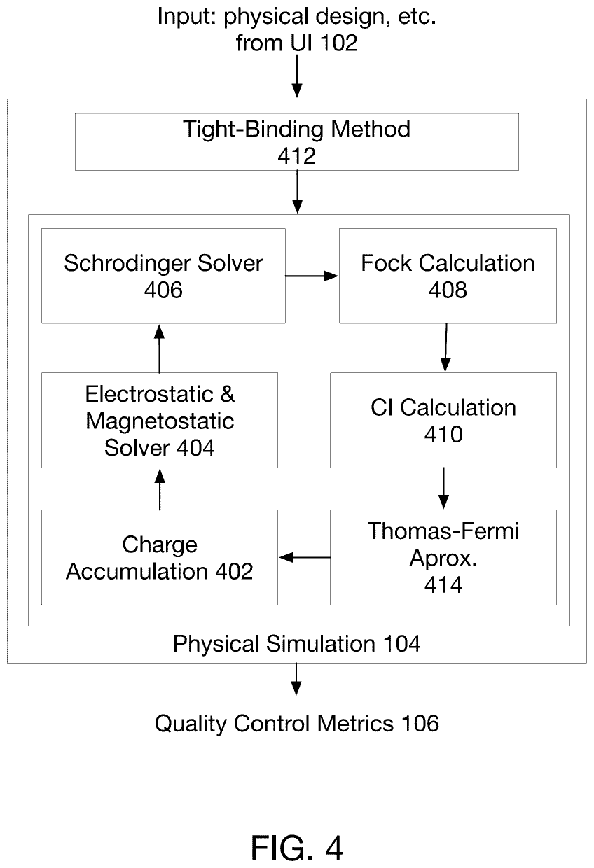

Returning to FIG. 1, user inputs provided through the UI 102 are delivered to a physical simulation module 104. Physical simulation module 104 performs the calculations discussed above and is illustrated in greater detail in FIG. 4. As shown, a number of sub-modules or solvers contribute to the physical modeling of the semiconductor qubits, with each sub-module depending on the output of its preceding sub-module.

Surface charge and current densities of the qubit system are determined by a charge accumulation sub-module 402. More particularly, charge accumulation module 402 is used to determine the surface charge and current densities of the physical qubit system. The surface charge density is determined from the predefined physical gate voltages. The system largely acts like a capacitor composed of positive (negative in the case of hole charge carriers) surface charge at the metallic gates and negative (positive in the case of hole charge carriers) surface charge at the 2DEG. Given that the semiconductor is insulated from the metal, there are three possible regimes of operation at the 2DEG: accumulation, depletion, and inversion. In the absence of doping a depletion region ceases to exist, leaving only accumulation and inversion regions. In Si/SiGe, spin qubits operate in the accumulation regime while in GaAs/AlGaAs, they operate under depletion. The regime of operation of the 2DEG largely depends on the semiconductor and metal work functions. The semiconductor work function requires prior knowledge of the semiconductor's quasi-Fermi energy, which can be determined iteratively using the Thomas-Fermi approximation (TFA). See Kane, Evan O., “Thomas-Fermi Approach to Impure Semiconductor Band Structure,” Phys. Rev. v. 131, no. 1, p. 79 (1963). Given that TFA depends on the surface charge density at the 2DEG, acquiring the correct surface charge density involves self-consistent iterations with TFA. In addition, the surface charge also depends on a small correction imposed by the quantum capacitance, which intrinsically depends on the lowest energy state within the quantum well.

Aside from the surface charge, surface currents at the 2DEG also contribute to spin qubits. The surface currents are used to measure discrete jumps in conductance due to changes in a quantum dot's charge occupation number and are formed by placing source and drain ohmic contacts far away from the quantum dot regime. Surface currents at the 2DEG are quantitatively determined by solving the drift-diffusion equation. See Markowich, P. A., Semiconductor Equations, Springer Science & Business Media (2012).

An electrostatic and magnetostatic solver 404 determines electric and magnetic fields, respectively, resulting from any applied physical gate voltages or micromagnetic islands. Electrostatic fields are defined by evaluating the Poisson integral, see, e.g., Eastwood, J. W. & Brownrigg, D. R. K., “Remarks on the solution of Poisson's equation for isolated systems, J. Comp. Phys., v. 32, no. 1, pp. 24-38 (1979), within the spectral representation to avoid the convolution procedure. Additionally, electrostatic fields can be determined by iteratively solving the Poisson equation using the conjugate gradient method, among other iterative procedures. Determining electrostatic fields requires the careful prescription of boundary conditions. These are easiest to prescribe through the facilities of a graphical user interface (GUI) included in UI 102. For various qubit systems of interest, metal-insulator boundaries adopt Dirichlet boundary conditions while insulator-insulator boundaries adopt Neumann boundary conditions. The surface charge density at the 2DEG is initially assumed to be homogeneous and thereafter (during self-consistency) defined by the prescribed Schrodinger equation's eigenfunctions and their respective occupation densities. The occupation probability of each of the eigenfunctions is determined by the TFA procedure. In the presence of ferromagnetic islands, micromagnetic simulations can be used to determine magnetostatic fields at the 2DEG region. This can be achieved by partitioning the ferromagnetic island into fine enough magnetization domains and propagating them using the time-dependent Landau-Lifshitz-Gilbert or Landau-Lifshitz-Bloch equation. See Nakatani, Y. et al., “Direct solution of the Landau-Lifshitz-Gilbert equation for micromagnetics,” Japan. J. Appl. Phys., v. 28 p. 2485 (1989); Atxitia, U. et al., “Fundamentals and applications of the Landau-Lifshitz-Bloch equation, J. Phys. D: Applied Phys. v. 50, no. 3, p. 033003 (2017).

A tight binding calculation module 412 utilizes tight binding calculations to extract parameters for computations used by a Schrodinger solver 406. That is, material-dependent parameters of the prescribed Schrodinger equation are extracted using atomistic calculations. In some instances, other atomistic methods may be used.

Some of the parameters extracted for use by the Schrodinger solver include the effective mass within EMT and MV-EMT and the conduction band offset, spin-orbit band shifts, valance band strain, conduction band strain, and Luttinger-Kohn parameters within the multi-band k.p method. Properly defining these parameters for semiconductors with material defects is non- trivial. For a defect-free semiconductor, the unit cell prescribed within the tight binding scheme is the semiconducting material's primitive cell structure. The band structure of the tight binding solution can be used to define the material parameters. In the presence of material defects, the unit cell needs to be extended to statistically include the relevant concentrations of material defects. This results in adjusted material parameters within the prescribed Schrodinger scheme. Furthermore, the material parameters can be spatially varied to include large deviations at the region of the spin qubit(s), allowing users to discern system and performance metrics more accurately.

The Schrodinger solver 406 is used to determine the ground-state eigenenergies and eigenfunctions of the qubit system in the absence of exchange and correlation. The self-consistent procedure of physical simulation 104: (a) determines the eigenenergies and eigenfunctions from the prescribed Schrodinger equation; (b) utilizes the eigenfunctions to determine the charge density of the system; (c) inputs the total particle number into the TFA procedure 414 to determine the occupation probability of each eigenenergy; and (d) evaluates the induced electrostatic potential and magnetostatic fields using the Poisson integral. The self-consistent iterations stop once changes in the effective scalar potential is below a user-specified threshold. The effective scalar potential is the sum over the conduction band offset at the quantum well and induced electrostatic potential, among other potential contributions which may be relevant.

The prescribed Schrodinger equation is either an effective mass theory (EMT) or an β-band k.p method. The 6- and 8-band k.p method has the advantage of accounting for orbital states, spin states, valley states, and their respective couplings. Each of the methods contain a set of spatially varying material parameters which need to be manually inputted. The spatial domain of the quantum region is confined to the QD regions and is only a subset of the electrostatic domain. This multi-scale scheme significantly reduces the computational complexity of the eigensolver, whose complexity scales as [symbol] (N²), where N is the number of grid points of a voxel-based mesh. External magnetic fields are integrated by gauge transforming the multi-band wavefunction (i.e., Perl's substitution) and considering any other necessary band couplings within the k.p method.

The exchange of the qubit system is computed by self-consistently determining the ground-state single Slater determinant (Fock operator) within the self-consistent procedure of a Fock calculation sub-module 408. Exchange effects are integrated into the eigenfunctions to accurately account for Pauli-spin blockade effects. This can be achieved by inserting the Fock operator within the prescribed Hamiltonian. The Fock operator is the single Slater determinant of the ground-state eigenfunctions. See Szabo, A., Modern Quantum Chemistry: Introduction to Advanced Electronic Structure Theory, Courier Corporation (2012). Unlike the induced electrostatic potential, the Fock operator is highly nonlocal and is best determined self-consistently. This can be achieved by first evaluating the N² components of the Fock operator using the eigenfunctions of module 4. Thereafter, the Fock operator is projected onto a manifold of occupied eigenfunctions and placed within the prescribed Hamiltonian to determine a new set of eigenfunctions. Once the Poisson-Schrodinger equation converges, a new Fock operator is calculated and the new set of eigenfunctions are compared with those of the previous. If the prescribed tolerance is satisfied, exchange has been properly integrated into the eigenfunctions, otherwise, a self-consistent procedure is simulated again with the new Fock operator. As opposed to the ˜ [symbol] (N³) complexity of traditional methodologies for calculating the Fock operator, the complexity of this procedure scales as ˜ [symbol] (N²). The computational bottleneck lies in calculating the Poisson integrals, which can be massively parallelized using graphical processing units (GPUs), Message Passing Interface (MPI), or Open Multiprocessing (OpenMP) schemes.

A configuration interaction (CI) sub-module 410 determines correlation of the system by correctly accounting for any relevant one- and two-electron correlations, along with any other relevant [symbol] -electron correlations for [symbol] =1,2, . . . , Nₑ, where Nₑ is the number of electrons within the QDs. Correlation effects are integrated using the configuration interaction method. See Rontani, M. et al., “Full configuration interaction approach to the few-electron problem in artificial atoms,” J. Chem. Phys. v. 124, no. 12, p. 124102 (2006) or Szabo, A., Modern Quantum Chemistry: Introduction to Advanced Electronic Structure Theory, Courier Corporation (2012). Although correlation is only a small subset of the overall contribution to the energy of spin qubits, it is particularly important for characterizing tunneling effects between neighboring dots. Like exchange, correlation can be calculated self-consistently but now accounts for a linear combination of single Slater determinants. Given the computational complexity of full CI, in some embodiments only a subset of the most significant correlations are calculated. For example, higher-order correlations can be calculated for multiple electrons on the same dot and electrons on neighboring quantum dots.

The point of the above-described physical simulation is to produce a set of quality control metrics 106 to characterize the qubit system. Qubit characterization is the process of tuning the quantum dots to the charge configuration of the qubit and defining the qubit's regimes of operation. The former is required to achieve the latter. With approximately seven physical gates per qubit, semiconductor qubits are more difficult to tune than other qubit platforms (e.g., superconducting, ion traps, etc.). Their number of control elements encompass an n-dimensional space, with n being the number of physical gates affecting a given qubit. One benefit, however, is that this large control space makes semiconductor qubits versatile for quantum control protocols.

In embodiments of the present invention, to determine the charge configuration of quantum dots, all the physical gates are initially set to a low voltage. In defining the desired number of electrons per dot, the voltages on the plunger gates, located directly above the dots, are gradually increased until the desired charge configuration is reached.

The number of electrons per dot is typically characterized by a charge diagram, whose dimensionality is equal to the number of quantum dots within the system. Once the desired charge configuration is reached, the voltages of the confining (screening and barrier) gates are gradually increased to reduce the barriers between the dots. With every change in the confining gates, the charge diagram shifts and the plunger gates are readjusted. In the absence of the present Q-TCAD system an iterative tuning procedure such as this can easily take many months, with its complexity growing for a larger number of qubits.

A qubit operation is defined by determining the range of voltages that maximize a certain set of quality control metrics and the optimal control axes for which its operation occurs. The qubit is characterized once the voltage range and control axes of all qubit operations are well defined. The qubit operations of semiconductor qubits include loading, initialization, readout, one-qubit operation, and two-qubit operation. Each of these procedures requires an optimization scheme to determine the voltage range (and magnetic field) required for a successful qubit operation. The cost functions of the optimization scheme are the qubit's prescribed quality control metrics 106.

By way of example, a tuning procedure for and quality control metrics of Loss-DiVincenzo (LD) spin qubits, one of a few promising architectures for universal quantum computing, may proceed as follows. First, in a loading procedure, an electron is transferred from an accumulation region onto a neighboring quantum dot. Within an LD qubit, the lowest-energy spin-up and spin-down states are separated by the Zeeman energy due to an applied uniform magnetic field. The loading procedure can be achieved using the Elzerman method, in which the voltage of the quantum dot's plunger gate is increased to the point where the quasi-Fermi energy is just above the lowest-energy spin-up state and below the next lowest spin-down state. After waiting some allotted time, an electron jumps from the accumulation gate to the quantum dot.

Next, in an initialization procedure, the qubit's initial state is set before the quantum computation commence. The Elzerman procedure can also be used to initialize the LD qubit. Indeed, by loading an electron, the qubit is automatically initialized to its lowest-energy spin-up state. Given an electron already exists within the quantum dot, it is first removed by decreasing the plunger gate voltage so that the quasi-Fermi energy is just below the lowest-energy spin-up state. Once the quantum dot is empty, a loading procedure can used to initialize the qubit.

In the readout procedure, a charge sensor is utilized to detect discrete variations in the charge configuration of its neighboring quantum dot. For LD qubits, this can also be achieved using the Elzerman procedure. Given that a single electron already occupies the quantum dot, the plunger gate voltage can be lowered so that the quasi-Fermi energy is just above the lowest-energy spin-up state and still below the next lowest spin-down state. Given that the spin-down state is occupied, after some time the electron within the quantum dot will tunnel to the accumulation gate and, thereafter, an electron will tunnel back into the lowest-energy spin-up state of the quantum dot. The resulting fluctuation in charge occupation will be detected by a neighboring quantum dot sensor. On the other hand, if the spin-up state is occupied, no fluctuation in charge occupation will occur, resulting in the readout of the LD qubit.

In a one-qubit operation, a gradient magnetic field is applied to the LD qubit using a ferromagnetic island. By use of the electric dipole resonance (EDR) technique, RF pulses are applied to each of the barrier gates belonging to the LD qubit's QD, with one RF pulse phase shifted from the other. This causes the electron to oscillate along the direction of the gradient magnetic field. An initial lowest-energy spin-up state will fluctuate between its spin up state and a superposition of spin-up and spin-down states, resulting in a Hadamard gate. In a two-qubit operation, the barrier gate voltage between two neighboring quantum dots is increased to pronounce tunneling effects between the LD qubits residing in each dot. After a period of time, the barrier gate voltage is once again decreased to its original value, finalizing the two-qubit operation for an LD qubit.

In the absence of the present invention, determining the regime for which the qubit operates can be a daunting task, requiring simulations over a range of voltages taking a significant amount of time. Using the present Q-TCAD system, after every automated physical simulation a set of quality control metrics 106 are generated that provide a strong indication of when the qubit operation is pronounced. By automatically and iteratively running self-consistent simulations, an optimization scheme can be used to determine the regime in voltage space where the qubit operates best. In some instances, the computational effort of the optimization procedure may be reduced by significantly reducing the tolerance threshold until a viable or acceptable set of quality control metrics is attained (i.e., changing gate voltages over a finite number of iterations of the Poisson-Schrodinger equation until quality control metrics are attained).

Thereafter, the present system defines control axes of each qubit operation. The control axes are contained within the qubit operation's predetermined voltage regime. Their prescribed path must be continuously differentiable (i.e., no sudden jumps in voltage should be present). To determine these axes the present system first finds the voltage set for which the qubit operation's quality control metrics are maximally pronounced. From this point in voltage space, the control axes are defined by determining a path that maximally optimizes the qubit operation's quality control metrics. Performance metrics are determined by propagating the qubit in time using dynamics simulators to perform the qubit operation. In one embodiment, this is done by mapping the physical model to an effective, as discussed below. Once the control axes are determined, a denser collection of voltage configurations along the control axes may be attained using physical simulations.

In some embodiments of the present invention, once the system is characterized, its fabrication yield is assessed. This involves accounting for a number of different considerations in order to predict a fabrication yield with confidence. This includes assessing the qubit tolerance to material defects, assuring functional safety and manufacture preparation, and incorporating quantum error correction requisites at the design level.

In some embodiments of the present Q-TCAD system, qubit tolerance to material defect concentrations is assessed at the component level. As semiconductor qubit component designs evolve, they will require mechanisms which can cope with material defects detrimental to the qubit's stability such as charge impurities, atomic steps at interfaces, and dangling bonds. Their effect on the system's fabrication yield can be statistically interpreted. This can be achieved by first running physical simulations of some configuration of material defects in the vicinity of the semiconductor spin qubit's QD(s). While some material defect configurations will be detrimental to the spin qubit, others will pose little issue. Once complete, the material defect concentration will be used to determine the probability of each configuration (or event). To determine the fabrication yield, performance metrics can be determined for each event and weighted by the probability of the event's occurrence. Another interesting route is to simulate the prescribed Schrodinger equation using spatially dependent material parameters extracted from band structures calculations that incorporate the specified material defect concentration. This can be achieved using tight-binding calculations, whereby the material defects are incorporated into the tight-binding unit cell.

Next, a functional safety stage and manufacturing preparation stage are undertaken. The functional safety stage consists of analysis, synthesis, and verification. The analysis stage simulates the failure-in-time (FIT) rates of the circuit design. The synthesis stage adds reliability components to the circuit to improve fault detection. The verification stage runs a “fault campaign” by inserting faults into the circuit design to verify the reliability of the circuit's functionality. The manufacturing preparation stage mainly consists of mask data preparation in which lithography photomasks are designed prior to chip fabrication. The preparation of such masks is well-known in the semiconductor industry and different foundries may have different requisites for preparing the photomasks.

Finally, the present system integrates quantum error correction requisites to help overcome functional errors. Some of the requisites include placing ancillary qubits at relevant locations and ensuring that coding distances are met within the physical layout. This step becomes more important as the number of qubits begins to significantly scale. Various quantum control protocols designed to suppress and mitigate functional errors, such as dynamic decoupling, are already incorporated at the outset.

Referring back to FIG. 1, once quality control metrics have been determined, the present system performs a modeling process 108 and dynamic simulation 110 to produce a set of performance metrics 112 for prescribed qubit operation. Determining the control signals, performance metrics, and ensuring scalability of semiconductor qubits requires introducing a level of abstraction to the physical models discussed previously. At first, the parameters of the effective models need to be characterized from observables generated by the physical simulations. Thereafter, the effective models need to be inserted within an open quantum system (OQS) solver to evaluate performance metrics for the semiconductor qubits. The relevant noise sources for different material platforms need to be defined and integrated into the OQS. Finally, quantum control protocols must be introduced to optimize control signals and the system design. In the absence of quantum control procedures, RF signals, along with any other input sources, are manually defined by the user.

At the modeling stage 108, introducing a level of abstraction to the physical models is achieved by initially defining a first-quantized effective Hamiltonian that matches the prescribed physical Hamiltonian. The effective Hamiltonian contains parameters such as the vertical effective mass, lateral effective mass, g-tensor, interdot exchange coupling, and the effective potential, among others. Each of these parameters is extracted from the quality control metrics 106 produced by the physical simulation 104. One example is the detuning between neighboring quantum dots, which can significantly vary for different gate voltage configurations. Another example is the interdot coupling strength, whose value is strongly dependent on exchange and correlation effects. These parameters' dependence on control signals can be determined by running physical simulations of the system for different configurations of gate voltages. Interpolation schemes can be used to extract configurations of the gate voltages that have not explicitly been simulated. In practical implementations of semiconductor qubits, the parameters of the effective Hamiltonian have a strong dependence on the physical gate voltages, external magnetic fields, temperature, and even the stress tensor.

Once the first-quantized effective Hamiltonian is fully defined, it is mapped to a second-quantized effective Hamiltonian. The second-quantized effective Hamiltonian is expanded to an operator basis such as the Pauli group. This operator basis contains a set of coefficients that must be specified by the first-quantized Hamiltonian. A set of these coefficients are chosen by symmetry considerations and calculated as the expectation value of the first-quantized Hamiltonian, with the eigenfunctions extracted from the physical simulations. As a result of the first-quantized Hamiltonian, each of the coefficients depend on the qubits' physical setting, defined by the physical gate voltages, magnetic field, temperature, and stress tensor. Given a range of physical setting configurations, quantum control protocols are used to better define a qubit operation's control signals (or control axes). In some cases, an alternative mapping procedure, such as a Schrieffer-Wolf transformation, may be used for effective modeling.

The present system makes use of dynamics simulators to assess the operational performance of a qubit architecture. This involves considerations of the environment in which the qubits operate. Semiconductor qubits have three main sources of noise from their environment: 1/f charge noise, spin dephasing due to hyperfine interactions, and phonon-mediated relaxation. Within the framework of quantum computing, a closed quantum system's environment is accounted for using a formal framework known as open quantum systems (OQS). An OQS incorporates environmental noise by adding a non-unitary component to either the Schrodinger or quantum Liouville equation. The result is called a quantum master equation. In one embodiment, the present system makes use of the Hamiltonian Open Quantum System Toolkit (HOQST) described by Chen, H. and Lidar, D. A., “HOQST: Hamiltonian Open Quantum System Toolkit,” Commun. Phys. v. 5, p. 112 (2022).

HOQST is a unique solver that simulates arbitrary time-dependent Hamiltonians with a variety of noise sources, including ohmic baths (which model phonon-mediated relaxation that occurs due to the emission of acoustic phonons coupled to a spin-mixing relaxation such as hyperfine or spin-orbit) and 1/f charge noise (which plays a dominant role in isotopically purified Si/SiGe and may be accounted for using a spin-fluctuator model). Hyperfine interactions are accounted for by coupling the spins of the system to a nuclear spin bath. As opposed to many gate-based approaches to OQS, HOQST accounts for the continuous driving of quantum systems due to the finite bandwidth of signal generators and controllers. In some embodiments of the present system, HOQST is modified through the introduction of tensor networks (TN), Quantum Monte Carlo (QMC) schemes, and alternative propagation methods to provide a scalable dynamic simulator (i.e., scalable with the number of qubits).

Defining a sufficient set of performance metrics 112 is important so as to provide the user with a reliable understanding of the subject quantum component(s) and quantum circuit. Accurate performance metrics can also ensure more reliable quantum control results. The crudest and most easily measurable metrics are the relaxation and decoherence times. The most common metric is the fidelity, typically used to assess the success probability of qubit storage (memory) and gate operations. An equivalent metric is the trace-norm distance; the two metrics (fidelity and distance) provide mutual upper and lower bounds. Randomized benchmarking is a relatively efficient method to experimentally estimate the fidelity, at the cost of not being able to capture non-Markovian effects due to the randomized nature of this approach. This set of metrics tries to capture performance in terms of a single number. At the other extreme is quantum state or process tomography, which gives complete information about the output state or gate operation. The number of measurements required for tomography scales exponentially in the number of qubits. Randomized benchmarking can be extended to incorporate gate set tomography, which provides a less costly approach to performing tomography.

Quantum control allows a user to optimize a semiconducting circuit to ensure maximal qubit performance. Quantum control optimizes the (time-dependent) coefficients of the effective Hamiltonian's operator basis expansion by targeting a specified cost function. The cost function can target any of the performance metrics, such as the fidelity of a given operation. In some embodiments of the present Q-TCAD system, open-source quantum control protocols tailored towards optimizing control signals, such as chopped random basis (CRAB) and gradient ascent pulse engineering (GRAPE), are adopted. More generally, control signals are adjusted to optimize the expansion coefficients and, given the unique connection of the physical and effective models present in the Q-TCAD system, the system design (including the prescribed materials and the geometric design of the physical gate layout) is optimized as well. The quantum control afforded by the present system thus provides a powerful combination of the control signals and qubit design required for high-fidelity qubit operations.

Thus, a computer-aided design system for quantum technology, and more specifically such a system for use in connection with the design, fabrication, and control of semiconducting quantum devices, has been described.

What is claimed is:

1. A quantum technology computer-aided design (Q-TCAD) system, comprising:
a user interface (UI) configured to allow a user to characterize a semiconductor-based qubit system by defining a physical architecture, prescribing materials, optimizing system properties, choosing quality control and performance metrics, specifying simulation preferences, and defining input signals for said semiconductor-based qubit system; and
a qubit modeling stage that is configured to receive user inputs through the UI and to run both physical and dynamic simulations of the semiconductor-based qubit system as specified through the UI, said simulations run using a set of solvers,
wherein the physical simulations:
employ a self-consistent Poisson-Schrodinger process that includes both Fock and Configuration Interaction calculations for generating a set of lowest-energy eigenenergies and eigenfunctions representing the semiconductor-based qubit system in the presence of DC gate voltages, and
evaluate quality control metrics of the semiconductor-based qubit system for a range of said gate voltages, and
wherein the dynamic simulations are facilitated through extraction of physical parameters of the semiconductor-based qubit system from the physical simulations to a first-quantized effective Hamiltonian, followed by a mapping of the first-quantized effective Hamiltonian to a second-quantized effective Hamiltonian used to dynamically model qubit operations within an open quantum system framework, the dynamic simulations entailing simulation of applications of sequences of RF pulses applied to gates of the semiconductor-based qubit system and evaluation of performance metrics for each such operation in the presence of dynamic noise sources.

2. The Q-TCAD system of claim 1, wherein the qubit modeling stage is configured to permit manual user definition of the semiconductor-based qubit system.

3. The Q-TCAD system of claim 1, wherein the qubit modeling stage is configured to permit definition of the semiconductor-based qubit system through receipt and automated analysis of one or more images of one or more elements of the semiconductor-based qubit system.

4. The Q-TCAD system of claim 3, wherein one of the images is a scanning electron micrograph (SEM) of a physical gate structure for semiconductor qubits of the semiconductor-based qubit system.

5. The Q-TCAD system of claim 1, wherein the qubit modeling stage is configured to permit qubit type characterization by one or more of physical makeup, atomic configuration, charge configuration, loading, readout, initialization, one-qubit operation, and two-qubit operation.

6. The Q-TCAD system of claim 1, wherein the qubit modeling stage is configured to permit user definition of one or more of material and physical design defects, including some or all of charge impurities, atomic steps, and dangling bonds, within a semiconducting heterostructure of the semiconductor-based qubit system.

7. The Q-TCAD system of claim 6, wherein the material and physical design defects are incorporated into the physical and dynamic simulations to account for fabrication yields during manufacture of the semiconducting heterostructure and fabrication of the semiconductor-based qubit system.

8. The Q-TCAD system of claim 1, wherein the solvers separate a semiconducting heterostructure of the semiconductor-based qubit system characterized through the UI into classical and quantum regimes, the classical regime being defined by a nonlinear Poisson equation with boundary conditions (BCs) applied to an exterior of the semiconducting heterostructure and a corresponding metal-semiconductor interface, and the quantum regime being characterized by either a multi-band k.p method, an effective mass theory (EMT), a nonperturbative multi-valley effective mass theory (MV-EMT), or a tight-binding (TB) scheme.

9. The Q-TCAD system of claim 1, wherein the solvers include a micromagnetic solver to characterize external magnetic field distribution from micromagnetic islands.

10. The Q-TCAD system of claim 1, wherein the solvers are configured to provide electrostatic or electromagnetic fields of collective DC and RF gates by evaluating a Poisson integral or evaluating a 4-vector (scalar-vector) potential in its integral (differential) form, respectively.

11. The Q-TCAD system of claim 1, wherein the qubit modeling stage is configured to run the physical and dynamic simulations recursively according to a specified optimization protocol, whether for qubit characterization or a quantum control protocol.

12. The Q-TCAD system of claim 1, wherein the semiconductor-based qubit system characterized through the UI is a model of a system that includes a plurality of semiconductor qubits, each of which is a collection of electrons trapped within a quantum dot (QD)-like structure, where the QDs are defined by adjusting voltages applied to physical gates above a semiconducting heterostructure.

13. The Q-TCAD system of claim 1, wherein the semiconductor-based qubit system characterized through the UI is a model of a system that includes a plurality of semiconductor qubits, where the semiconductor qubits are: charge qubits, donor qubits, color centers, or other qubits operated within semiconducting materials.

14. The Q-TCAD system of claim 1, wherein the dynamic noise sources are one or more of 1/f charge noise, spin dephasing due to hyperfine interactions, and phonon-mediated relaxation.

15. The Q-TCAD system of claim 1, wherein as part of the physical simulations atomistic calculations are used to extract material parameters for a prescribed Schrodinger equation.

16. The Q-TCAD system of claim 15, wherein the atomistic calculations comprise tight binding calculations.

17. The Q-TCAD system of claim 15, wherein the material parameters extracted for a prescribed Schrodinger equation include one or more of an effective mass within a nonperturbative multi-valley effective mass, a conduction band offset, spin-orbit band shifts, valance band strain, conduction band strain, and Luttinger-Kohn parameters.

18. A quantum technology computer-aided design (Q-TCAD) system, comprising:
a user interface (UI) configured to allow a user to characterize a semiconductor-based qubit system by defining a physical architecture, prescribing materials, optimizing system properties, choosing quality control and performance metrics, specifying simulation preferences, and defining input signals for said semiconductor-based qubit system; and
a qubit modeling stage that is configured to receive user inputs through the UI and to run both physical and dynamic simulations of the semiconductor-based qubit system, wherein the physical simulations produce quality control metrics for the semiconductor-based qubit system and the dynamic simulations produce performance metrics of qubit operations.

19. The Q-TCAD system of claim 18, wherein the physical parameters of the semiconductor-based qubit system extracted from physical simulations are placed within a first-quantized effective Hamiltonian which is mapped to a second-quantized effective Hamiltonian used to dynamically model the qubit operations.

20. The Q-TCAD system of claim 19, wherein the first-quantized effective Hamiltonian is mapped to a second-quantized effective Hamiltonian by a Schrieffer-Wolf transformation.
